(19) United States
(12) Patent Application Publication
(10) Pub. No.: US 2013/0320445 A1
(43) Pub. Date: Dec. 5, 2013

(54) HIGH VOLTAGE METAL-OXIDE-SEMICONDUCTOR TRANSISTOR DEVICE

(71) Applicants: Ming-Tsung Lee, Yilan County (TW); Cheng-Hua Yang, Hsinchu City (TW); Shih-Chieh Pu, New Taipei City (TW); Wen-Fang Lee, Hsinchu City (TW); Chih-Chung Wang, Hsinchu City (TW)

(72) Inventors: Ming-Tsung Lee, Yilan County (TW); Cheng-Hua Yang, Hsinchu City (TW); Shih-Chieh Pu, New Taipei City (TW); Wen-Fang Lee, Hsinchu City (TW); Chih-Chung Wang, Hsinchu City (TW)

(21) Appl. No.: 13/487,268

(22) Filed: Jun. 4, 2012

(51) Int. Cl. H01L 29/78

(52) U.S. Cl. 257/339; 257/E29.261

(57) ABSTRACT

A high voltage metal-oxide-semiconductor (HV MOS) device includes a substrate, a gate positioned on the substrate, a drain region formed in the substrate, a source region formed in the substrate, a first doped region formed in between the drain region and the source region, and a second doped region formed over a top of the first doped region or/and under a bottom of the first doped region. The drain region, the source region, and the second doped region include a first conductivity type, the first doped region includes a second conductivity type, and the first conductivity type and the second conductivity type are complementary.

### BACKGROUND OF THE INVENTION

1. Field of the Invention

The invention relates to a high voltage metal-oxide-semiconductor (herein after abbreviated as HV MOS) device, and more particularly, to a high voltage lateral double-diffused metal-oxide-semiconductor (HV-LDMOS) device.

2. Description of the Prior Art

Double-diffused MOS (DMOS) transistor devices have drawn much attention in power devices having high voltage capability. The conventional DMOS transistor devices are categorized into vertical double-diffused MOS (VDMOS) transistor device and lateral double-diffused MOS (LDMOS) transistor device. Having advantage of higher operational bandwidth, higher operational efficiency, and convenience to be integrated with other integrated circuit due to its planar structure, LDMOS transistor devices are prevalently used in high operational voltage environment such as CPU power supply, power management system, AC/DC converter, and high-power or high frequency (HF) band power amplifier. The essential feature of LDMOS transistor device is a lateral-diffused drift region with low dope concentration and large area. The drift region is used to alleviate the high voltage between the drain and the source, therefore the LDMOS transistor device can have higher breakdown voltage.

Please refer to FIG. 1, which is a cross-sectional view of a conventional HV-LDMOS transistor device. As shown in FIG. 1, the conventional HV-LDMOS transistor device 10 having a P-type well 20, a source 14 and a P-type heavily doped region 22 formed in the P-type well 20, a gate 16 and a drain 18 is formed on a semiconductor substrate 12. The drain 18 is an N-type heavily doped region formed in an N-type well 30, which is the drift region as mentioned above. The dope concentration and length of the drift region 30 affects the breakdown voltage and the ON-resistance (R_{ON}) of the HV-LDMOS transistor device 10. The gate 16 of the HV-LDMOS transistor device 10 is positioned on a gate dielectric layer 40 and extended to cover a portion of a field oxide layer 42.

It is well-known that characteristics of low R_{ON} and high breakdown voltage are always required to the HV MOS transistor device. However, breakdown voltage and R_{ON} are conflicting parameters with a trade-off relationship. Therefore, a HV LDMOS transistor device that is able to realize high breakdown voltage and low R_{ON} is still in need.

### SUMMARY OF THE INVENTION

According to a first aspect of the present invention, a HV MOS transistor device is provided. The HV MOS transistor device includes a substrate, a gate positioned on the substrate, a drain region formed in the substrate, a source region formed in the substrate, a first doped region formed in between the drain region and the source region, and a second doped region formed over a top of the first doped region. The drain region, the source region, and the second doped region include a first conductivity type, the first doped region includes a second conductivity type, and the first conductivity type and the second conductivity type are complementary.

According to a second aspect of the present invention, a HV MOS transistor device is provided. The HV MOS transistor device includes a substrate, a gate positioned on the substrate, a drain region formed in the substrate, a source region formed in the substrate, a first doped region formed in between the drain region and the source region, and a second doped region formed under a bottom of the first doped region. The drain region, the source region, and the second doped region include a first conductivity type, the first doped region includes a second conductivity type, and the first conductivity type and the second conductivity type are complementary.

According to a third aspect of the present invention, a HV MOS transistor device is provided. The HV MOS transistor device includes a substrate, a gate positioned on the substrate, a drain region formed in the substrate, a source region formed in the substrate, a first doped region formed in between the drain region and the source region, and a pair of second doped regions respectively formed over a top of the first doped region and under a bottom of the first doped region. The drain region, the source region, and the second doped regions include a first conductivity type, the first doped region includes a second conductivity type, and the first conductivity type and the second conductivity type are complementary.

According to the HV MOS transistor device provided by the present invention, the first doped region is rendered to improve the breakdown voltage of the HV MOS transistor device. Furthermore, the second doped region formed over the top of the first region or/and under the bottom of the first doped region is provided to decrease R_{ON}. Briefly speaking, the HV MOS transistor device provided by the present invention simultaneously realize the expectation of high breakdown voltage and low R_{ON}.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view of a conventional HV-LDMOS transistor device.

FIG. 2 is a schematic drawing of a layout pattern of a HV MOS transistor device provided by a first to a third preferred embodiments of the present invention.

FIG. 3 is a cross-sectional view of the HV MOS transistor device provided by the first preferred embodiment of the present invention taken along line A-A′ of FIG. 2.

FIGS. 4 and 5 are schematic drawings respectively illustrating a modification to the preferred embodiment.

FIG. 6 is a cross-sectional view of the HV MOS transistor device provided by the second preferred embodiment of the present invention taken along line A-A′ of FIG. 2.

FIG. 7 is a cross-sectional view of the HV MOS transistor device provided by the third preferred embodiment of the present invention taken along line A-A′ of FIG. 2.

FIG. 8 is a schematic drawing of a layout pattern of a HV MOS transistor device provided by a fourth to a sixth preferred embodiments of the present invention.

FIGS. 9-10 are cross-sectional views of the HV MOS transistor device respectively taken along line B-B′ and line C-C′ of FIG. 8.

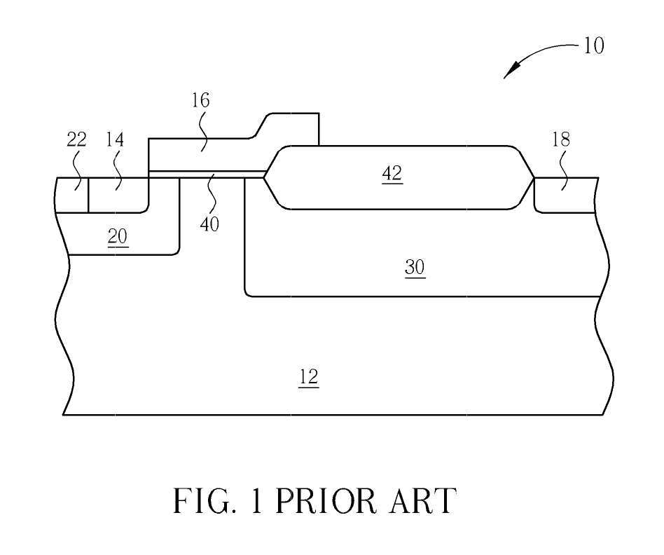

### DETAILED DESCRIPTION

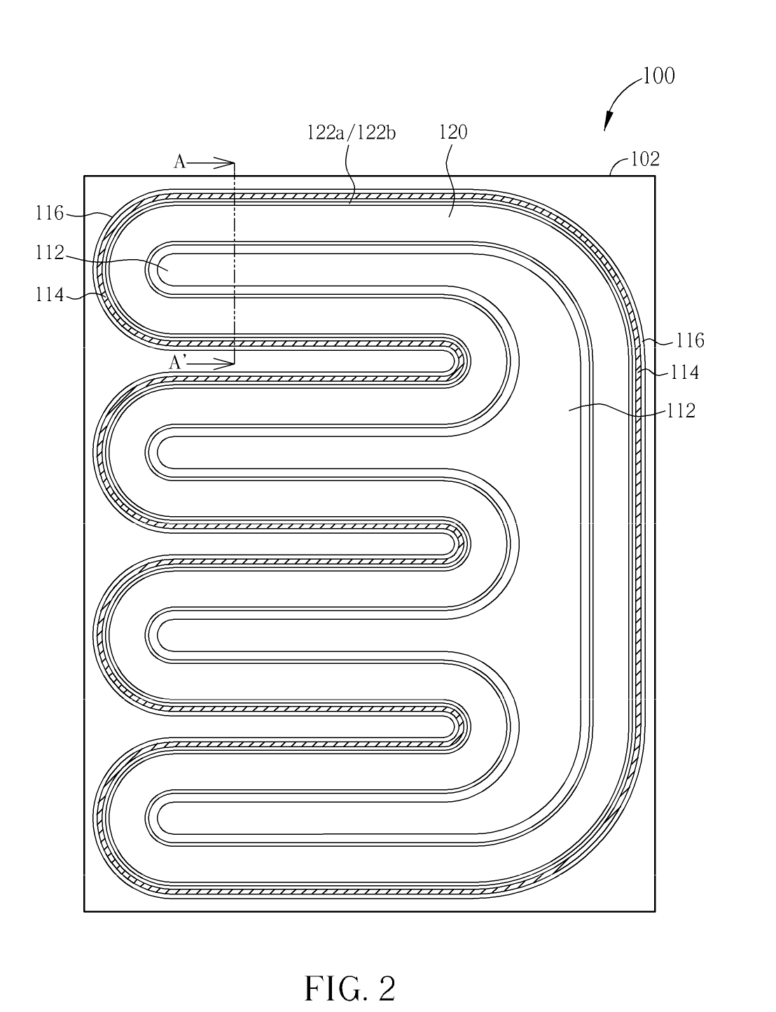

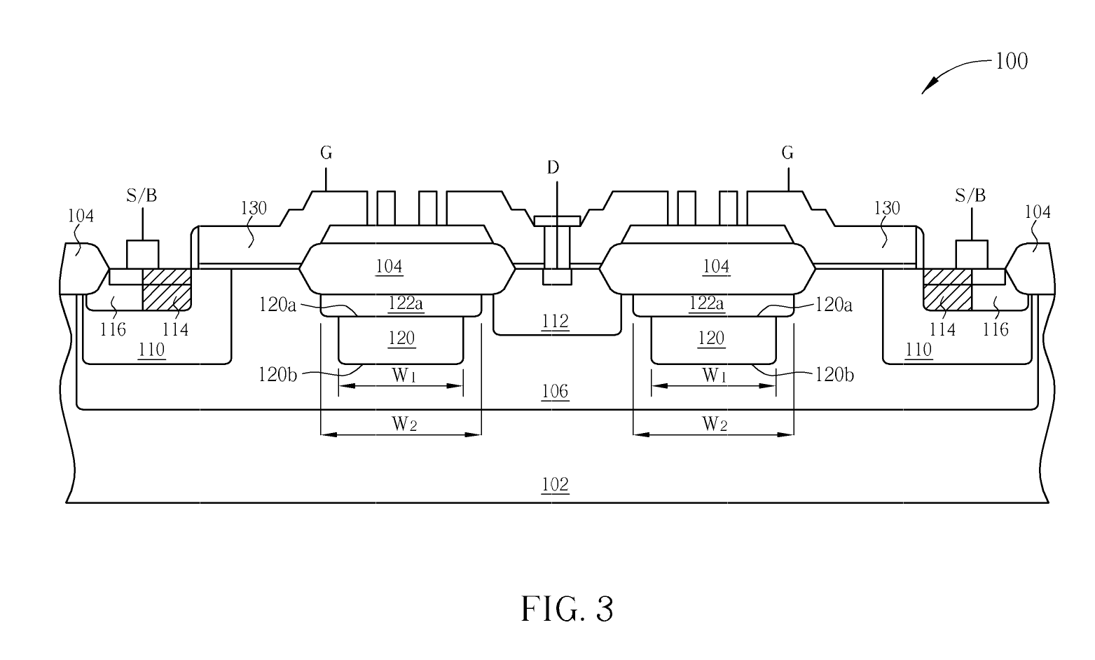

Please refer to FIGS. 2 and 3, FIG. 2 is a schematic drawing of a layout pattern of a HV MOS transistor device provided by a first to a third preferred embodiments of the present invention, and FIG. 3 is a cross-sectional view of the HV MOS transistor device provided by the first preferred embodiment taken along line A-A′ of FIG. 2. As shown in FIGS. 2 and 3, a HV MOS transistor device 100 provided by the preferred embodiment is positioned in a substrate 102, such as a silicon substrate. The substrate 102 includes a first conductivity type. In the preferred embodiment, the first conductivity type is p type. The HV MOS transistor device 100 further includes an insulating layer 104. It is noteworthy that for clarifying spatial relationships between certain specific doped regions of the HV MOS transistor device 100, the insulating layer 104 is omitted from FIG. 2. However, those skilled in the art would easily realize the location where the insulating layer 104 is to be formed according to FIG. 3.

Please still refer to FIGS. 2 and 3. The HV MOS transistor device 100 provided by the first preferred embodiment further includes a deep well 106 having a second conductivity type. The second conductivity type and the first conductivity type are complementary to each other. Accordingly, the second conductivity type is n type in the preferred embodiment. A drift region (not shown) and a high-voltage well region 110 (shown in FIG. 3) are formed in the deep well 106. The drift region includes the second conductivity type while the high-voltage well region 110 includes the first conductivity type. A drain doped region 112 is formed in the n-type drift region while a source doped region 114 and a body doped region 116 are formed in the p-type high-voltage well region 110. The drain doped region 112 and the source doped region 114 include the second conductivity type and respectively serve as an n-type drain (n-drain) region 112 and an n-type source (n-source) region 114 for the HV MOS transistor device 100. The body doped region 116 includes the first conductivity type and thus serves as a p-type body (p-body) region 116 for the HV MOS transistor device 100. In addition, the p-body region 116 and the n-source region 114 are electrically connected as shown in FIGS. 2 and 3. Furthermore, a drain contact (not shown), a source contact (not shown), and a body contact (not shown) can be formed respectively in the n-drain region 112, the n-source region 114, and the p-body region 116.

The HV MOS transistor device 100 also includes a gate 130. The gate 130 is omitted from FIG. 2 in order to clarify spatial relationships between certain specific doped regions of the HV MOS transistor device 100. However those skilled in the art would easily realize the location where the gate 130 is to be formed according to FIG. 3. As shown in FIG. 3, the gate 130 is positioned on the substrate 102 and covers a portion of the insulating layer 104.

Please still refer to FIGS. 2 and 3. The HV MOS transistor device 100 provided by the preferred embodiment further includes a first doped region 120. As shown in FIGS. 2 and 3, the first doped region 120 is positioned in between the n-drain region 112 and the n-source region 114. The drain region 112, the source region 114, and the first doped region 120 formed in the deep well 106 are not only spaced apart from each other, but also electrically isolated from each other by the deep well 106. The first doped region 120 includes a top 120a and a bottom 120b. As shown in FIGS. 2 and 3, the HV MOS transistor device 100 further includes a second doped region 122a formed in between the drain region 112 and the source region 114. More important, the second doped region 122a is formed over the top 120a of the first doped region 120. The first doped region 120 includes the first conductivity type, therefore the first doped region 120 is a p-doped region. The second doped region 122a includes the second conductivity type, therefore the second doped region 122a is an n-doped region. More important, the first doped region 120 includes a first dope concentration, the second doped region 122a includes a second dope concentration, and the second dope concentration is smaller than the first dope concentration. For example, when the first dope concentration is 4*10¹² (4E12), the second dope concentration is smaller than 2*10¹² (2E12), but not limited to this.

Please refer to FIGS. 2 and 3. According to the HV MOS transistor device 100 provided by the preferred embodiment, the first doped region 120 includes a width W₁, the second doped region 122a includes a width W₂, and the width W₂ of the second doped region 122a is larger than the width W₁ of the first doped region 120. It is noteworthy that the layout pattern shown in FIG. 2 is provided to illustrate the spatial relationship between the first doped region 120 and the second doped region 122a in the horizon plane, but not to limit the spatial relationship between the first doped region 120 and the second doped region 122a in the vertical plane.

According to the preferred embodiment, the p-type first doped region 120 being formed under the insulating layer 104 and complementary to the n-source region 114 and the n-drain region 112 increases the resistance of the HV MOS transistor device 100. When high voltage signal (HV signal) passes through the p-type first doped region 120, the voltage step-down ability of the HV MOS transistor device 100 is consequently improved and the acceptable lower voltage signal is obtained. In other words, by providing the p-type first doped region 120, the breakdown voltage of the HV MOS transistor device 100 is efficaciously increased. However, it is well known that R_{ON} is always undesirably increased in accompaniment of the increased breakdown voltage. Therefore the preferred embodiment provides the second doped region 122a formed over the top 120a of the first doped region 120. The second doped region 122a serves as an easy pathway for the electrons and thus R_{ON} is efficaciously reduced. As mentioned above, since breakdown voltage and R_{ON} are conflicting parameters with a trade-off relationship, the width W₂ of the second doped region 122a must be larger than the width W₁ of the first doped region 120, and the dope concentration of the second doped region 122a must be smaller than the dope concentration of the first doped region 120. Consequently, R_{ON} can be reduced while the expectation of high breakdown voltage is still met.

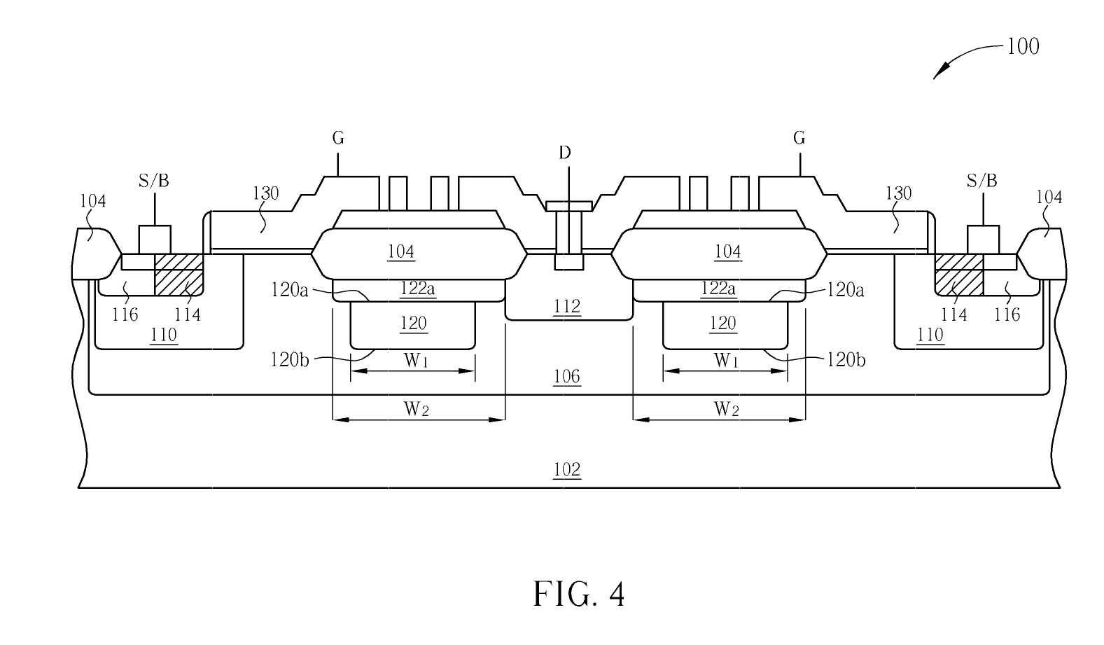

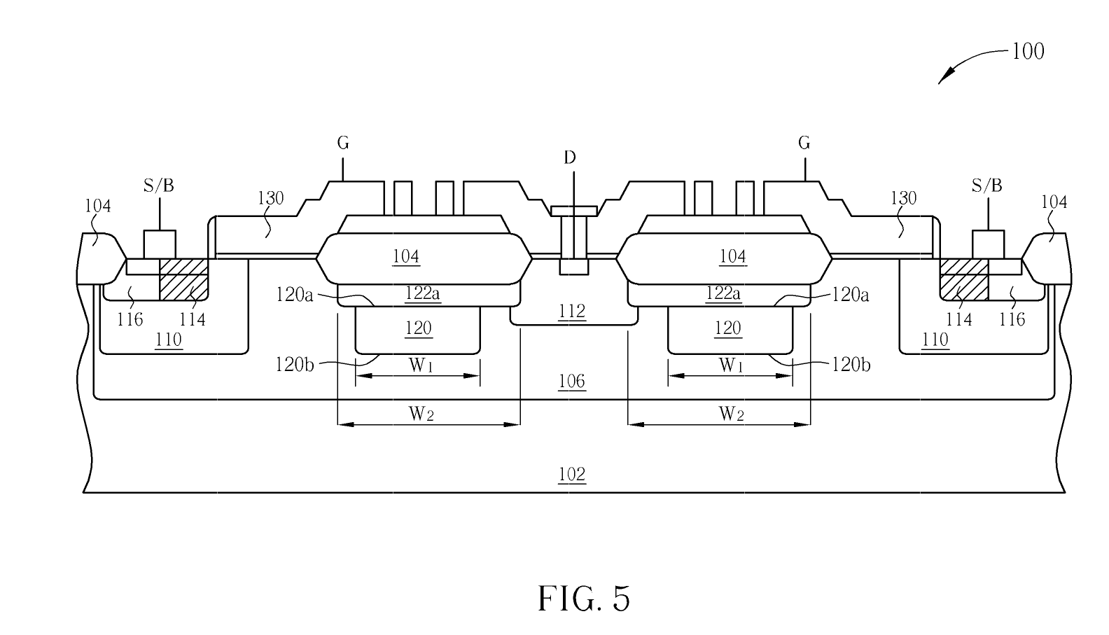

Please refer to FIGS. 4 and 5, which are schematic drawings respectively illustrating a modification to the preferred embodiment. According to the modification shown in FIG. 4, the second doped region 122a contacts the drain region 112. According to the modification shown in FIG. 5, the second doped region 122a overlaps with the drain region 122. According to the modifications provided by the present invention, the second doped region 122a contacts or even overlaps with the drain region 112 further reduces R_{ON}.

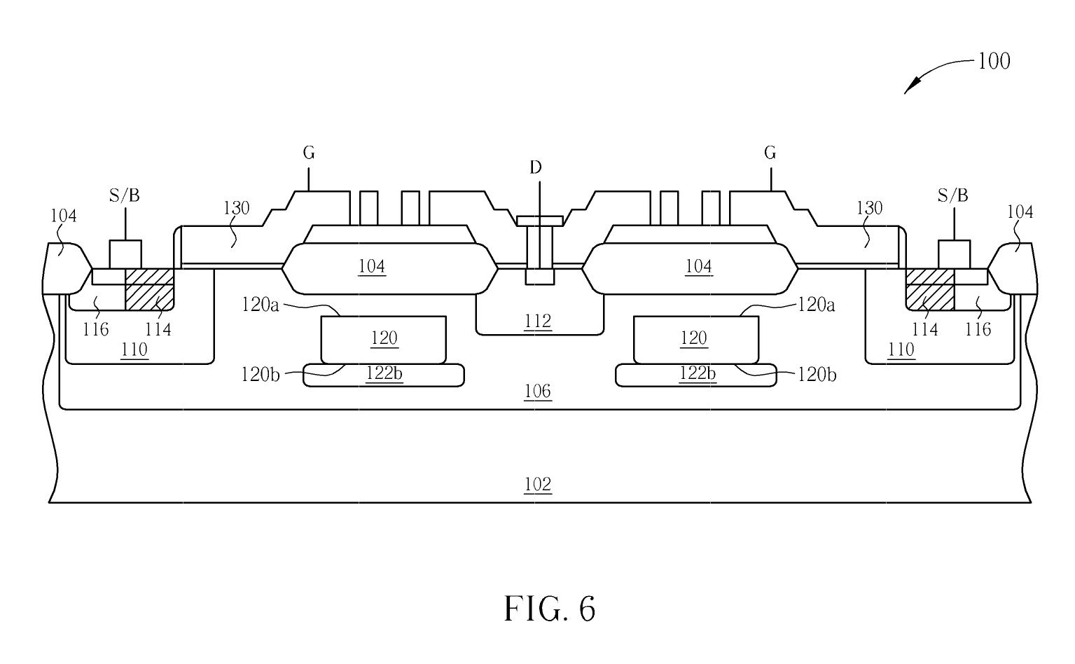

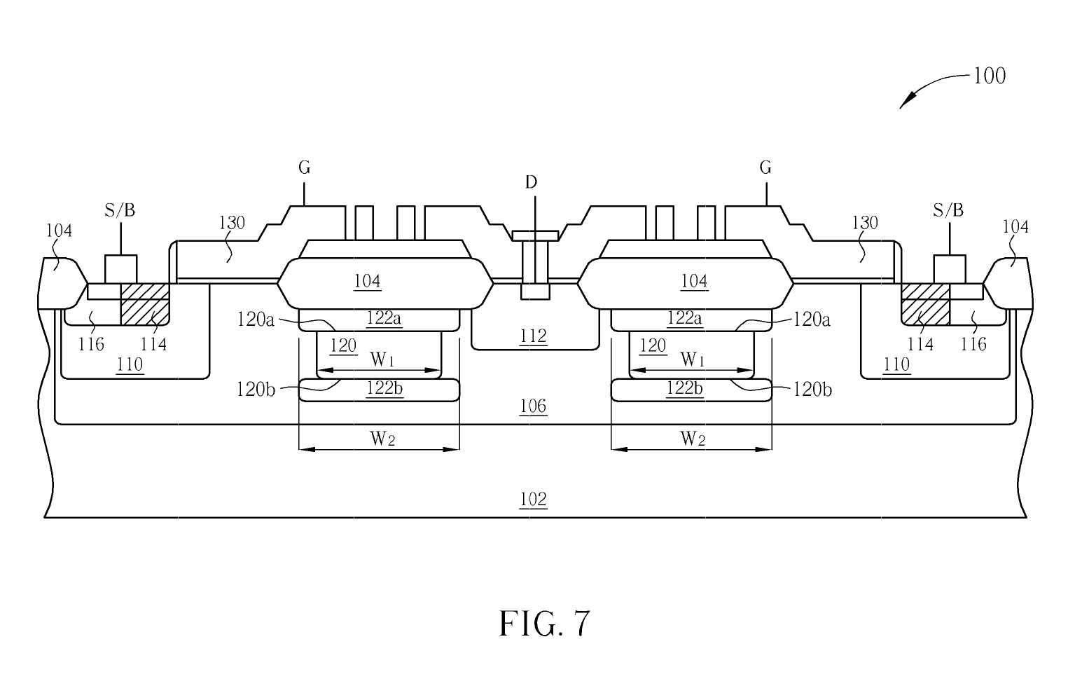

Please refer to FIG. 2 and FIGS. 6-7, wherein FIG. 6 is a cross-sectional view of the HV MOS transistor device provided by the second preferred embodiment taken along line A-A′ of FIG. 2 and FIG. 7 is a cross-sectional view of the HV MOS transistor device provided by the third preferred embodiment taken along line A-A′ of FIG. 2. As mentioned above, the layout pattern shown in FIG. 2 is provided to illustrate the spatial relationship between the first doped region 120 and the second doped region 122a in the horizon plane, but not to limit the spatial relationship between the first doped region 120 and the second doped region 122a in the vertical plane, therefore the layout pattern shown in FIG. 2 also illustrate the second and third preferred embodiments. Additionally, elements in the first, the second, and the third preferred embodiments are all designated by the same numerals and thus details are all omitted in the interest of brevity.

As shown in FIGS. 2 and 6, the difference between the first preferred embodiment and the second preferred embodiment is: The HV MOS transistor device 100 provided by the second preferred embodiment includes a second doped region 122b formed under the bottom 120b of the first doped region 120. As shown in FIGS. 2 and 7, the difference between the first preferred embodiment and the third preferred embodiment is: The HV MOS transistor device 100 provided by the third preferred embodiment includes a pair of second doped regions 122a/122b, respectively formed over the top 120a of the first doped region 120 and under the bottom 120b of the first doped region 120. Furthermore, the second doped region 122a formed over the top 120b of the first doped region 120 can be formed to contact the drain region 112, even to overlap with the drain region 122 in the third preferred embodiment.

According to the preferred embodiments, the p-type first doped region 120 being formed under the insulating layer 104 and complementary to the n-source region 114 and the n-drain region 112 increases the resistance of the HV MOS transistor device 100. The second and third preferred embodiments further provide the second doped region 122b formed under the bottom 120b of the first doped region 120 or/and the second doped region 122a formed over the top 120a of the first doped region 120. The second doped region 122a/122b serves as an easy pathway for the electrons and thus R_{ON} is efficaciously reduced. As mentioned above, since breakdown voltage and R_{ON} are conflicting parameters with a trade-off relationship, the width W₂ of the second doped region 122a/122b must be larger than the width W₁ of the first doped region 120, and the dope concentration of the second doped region 122a/122b must be smaller than the dope concentration of the first doped region 120. Consequently, R_{ON} can be reduced while the expectation of high breakdown voltage is still met.

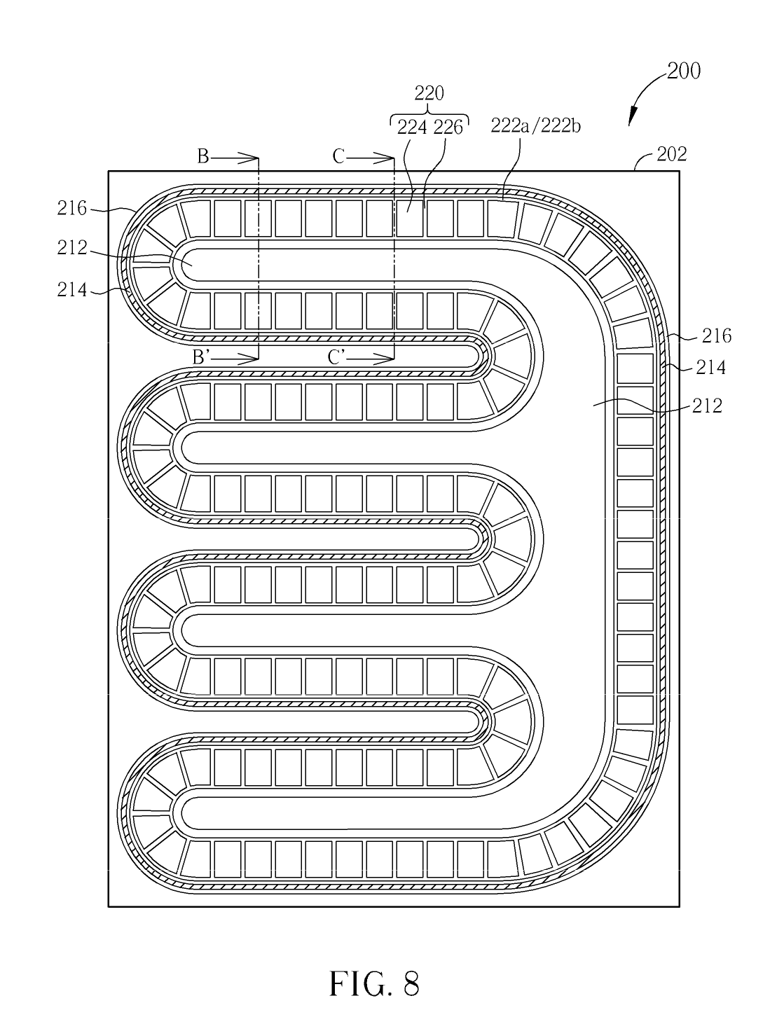

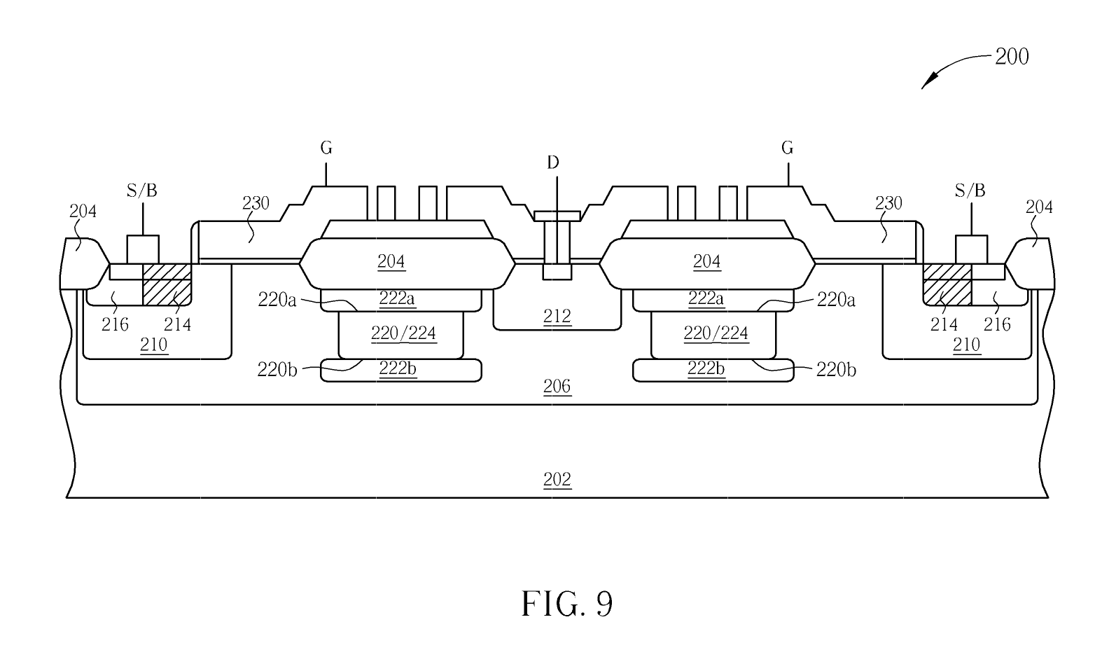

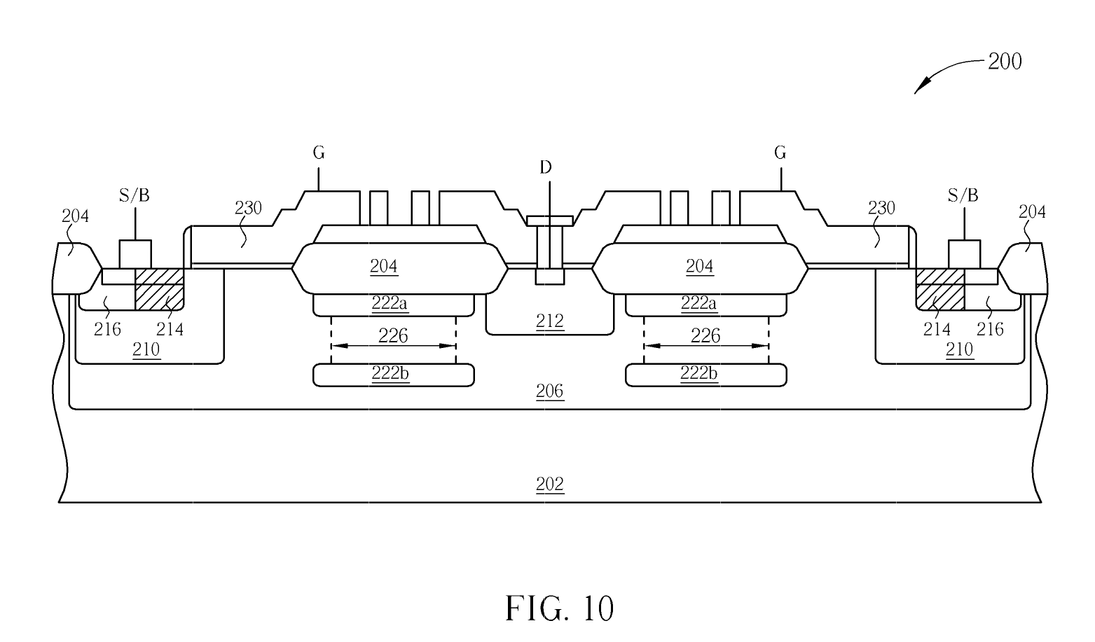

Please refer to FIGS. 8-10, wherein FIG. 8 is a schematic drawing of a layout pattern of a HV MOS transistor device provided by a fourth to a sixth preferred embodiments of the present invention, and FIGS. 9-10 are cross-sectional views of the HV MOS transistor device respectively taken along line B-B′ and line C-C′ of FIG. 8. As shown in FIGS. 8-10, a HV MOS transistor device 200 provided by the preferred embodiment is positioned in a substrate 202. The substrate 202 includes a first conductivity type. In the preferred embodiment, the first conductivity type is p type. The HV MOS transistor device 200 further includes an insulating layer 204. As mentioned above, for clarifying spatial relationships between certain specific doped regions of the HV MOS transistor device 200, the insulating layer 204 is omitted from FIG. 8. However, those skilled in the art would easily realize the location where the insulating layer 204 is to be formed according to FIGS. 9-10.

Please still refer to FIGS. 8-10. The HV MOS transistor device 200 provided by the preferred embodiments further includes a deep well 206 having a second conductivity type. The second conductivity type and the first conductivity type are complementary to each other. Accordingly, the second conductivity type is n type in the preferred embodiment. A drift region (not shown) and a high-voltage well region 210 (shown in FIGS. 9-10) are formed in the deep well 206. The drift region includes the second conductivity type while the high-voltage well region 210 includes the first conductivity type. A drain doped region 212 is formed in the n-type drift region while a source doped region 214 and a body doped region 216 are formed in the p-type high-voltage well region 210. The drain doped region 212 and the source doped region 214 include the second conductivity type and respectively serve as an n-drain region 212 and an n-source region 214 for the HV MOS transistor device 200. The body doped region 216 includes the first conductivity type and thus serves as a p-body region 216 for the HV MOS transistor device 200. In addition, the p-body region 216 and the n-source region 214 are electrically connected as shown in FIGS. 8-10. Furthermore, a drain contact (not shown), a source contact (not shown), and a body contact (not shown) can be formed respectively in the n-drain region 212, the n-source region 214, and the p-body region 216.

The HV MOS transistor device 200 also includes a gate 230. The gate 230 is omitted from FIG. 8 in order to clarify spatial relationships between certain specific doped regions of the HV MOS transistor device 200. However those skilled in the art would easily realize the location where the gate 230 is to be formed according to FIGS. 9-10. As shown in FIGS. 9-10, the gate 230 is positioned on the substrate 202 and covers a portion of the insulating layer 204.

Please still refer to FIGS. 8-10. The HV MOS transistor device 200 provided by the preferred embodiment further includes a first doped region 220. As shown in FIGS. 8-10, the first doped region 220 is positioned in between the n-drain region 212 and the n-source region 214. The drain region 212, the source region 214, and the first doped region 220 formed in the deep well 206 are not only spaced apart from each other, but also electrically isolated from each other by the deep well 206. The first doped region 220 includes a top 220a and a bottom 220b. More important, the first doped region 220 is a non-continuous doped region 220 according to the fourth to sixth preferred embodiments. As shown in FIGS. 8-10, the non-continuous first doped region 220 includes a plurality of doped regions 224 and a plurality of gaps 226. The doped regions 224 include the first conductivity type and thus are all p-doped regions 224.

As shown in FIG. 8, the p-doped regions 224 and the gaps 226 are arranged alternately. Accordingly each p-doped region 224 is adjacent to a gap 226. Furthermore, as shown in FIGS. 8-10, the insulating layer 204 covers the entire non-continuous first doped region 220. In other words, the insulating layer 204 entirely covers the p-doped regions 224 and the gaps 226 (shown in FIGS. 9-10). It is noteworthy that a ratio between a total area of the gaps 226 and a total area of the non-continuous first doped region 220 is to be smaller than or equal to 20% according to the preferred embodiment. A width W₃ of the gaps 226 is smaller than or equal to 9 micrometer (μm). Additionally, pattern density of the gaps 226 is adjustable according to different product or process requirements.

As shown in FIGS. 8-10, the HV MOS transistor device 200 provided by the fourth to sixth preferred embodiments further includes a second doped region 222a or/and a second doped region 222b formed in between the drain region 212 and the source region 214. More important, the second doped region 222a is formed over the top 220a of the first doped region 220 according to the fourth preferred embodiment, the second doped region 222b is formed under the bottom 220b of the first doped region 220 according to the fifth preferred embodiment, the pair of second doped regions 222a/222b are respectively formed over the top 220a of the first doped region 220 and under the bottom 220b of the first doped region 220 according to the sixth preferred embodiment. The second doped regions 222a/222b include the second conductivity type, therefore the second doped region 222a/222b is an n-doped region. More important, the first doped region 220 includes a first dope concentration, the second doped region 222a/222b includes a second dope concentration, and the second dope concentration is smaller than the first dope concentration. For example, when the first dope concentration is 4*10¹² (4E12), the second dope concentration is smaller than 2*10¹² (2E12), but not limited to this. As shown in FIG. 10, since the first doped region 220 is an non-continuous doped region, the second doped region 222a/222b also is formed over or/and under the gaps 226.

Please still refer to FIGS. 8-10. According to the HV MOS transistor device 200 provided by the preferred embodiments, the first doped region 220 includes a width W₁, the second doped region 222a/222b includes a width W₂, and the width W₂ of the second doped region 222a/222b is larger than the width W₁ of the first doped region 220. It is noteworthy that the layout pattern shown in FIG. 8 is provided to illustrate spatial relationship between the first doped region 220 and the second doped region 222a/222b in the horizon plane, but not to limit the spatial relationship between the first doped region 220 and the second doped region 222a/222b in the vertical plane.

Additionally, the second doped region 222a formed over the top 220a of the first doped region 220 can be provided to contact the drain region 212, even to overlap with the drain region 212 according to the fourth and sixth preferred embodiments.

According to the preferred embodiments, the p-doped regions 224 of the non-continuous first doped region 220 being formed under the insulating layer 204 and complementary to the n-source region 214 and the n-drain region 212 increases the resistance of the HV MOS transistor device 200. When HV signal passes through the p-doped regions 224, the voltage step-down ability of the HV MOS transistor device 200 is consequently improved and the acceptable lower voltage signal is obtained. In other words, by providing the p-doped regions 224, the breakdown voltage of the HV MOS transistor device 200 is efficaciously increased. However, it is well known that R_{ON} is always undesirably increased in accompaniment of the increased breakdown voltage. Therefore the preferred embodiment provides the gaps 226 interrupting in the non-continuous doped region 220. The gaps 226 are provided to lower the total doped area of the p-doped regions 224 therefore R_{ON} is efficaciously reduced.

More important, the fourth to sixth preferred embodiments further provide the second doped region 222a or/and 222b formed over the top 220a of the first doped region 220 or/and under the bottom 220b of the first doped region 220. The second doped region 222a/222b serves as an easy pathway for the electrons and thus R_{ON} is efficaciously reduced. As mentioned above, since breakdown voltage and R_{ON} are conflicting parameters with a trade-off relationship, the width W₂ of the second doped region 222a/222b must be larger than the width W₁ of the first doped region 220, and the dope concentration of the second doped region 222a/222b must be smaller than the dope concentration of the first doped region 220. Consequently, R_{ON} can be reduced while the expectation of high breakdown voltage is still met.

According to the HV MOS transistor device provided by the present invention, the first doped region is rendered to improve the breakdown voltage of the HV MOS transistor device. Furthermore, the second doped region formed over the top of the first region or/and under the bottom of the first doped region is provided to decrease R_{ON}. Briefly speaking, the HV MOS transistor device provided by the present invention simultaneously realize the expectation of high breakdown voltage and low R_{ON}.

Those skilled in the art will readily observe that numerous modifications and alterations of the device and method may be made while retaining the teachings of the invention. Accordingly, the above disclosure should be construed as limited only by the metes and bounds of the appended claims.

1. A high voltage metal-oxide-semiconductor (HV MOS) transistor device comprising:
a substrate;
a gate positioned on the substrate;
a drain region formed in the substrate, the drain region having a first conductivity type;
a source region formed in the substrate, the source region having the first conductivity type;
a first doped region formed in between the source region and the drain region, the first doped region having a second conductivity type complementary to the first conductivity type; and
a second doped region formed over a top of the first doped region, the second doped region having the first conductivity type,
wherein the first doped region and the second doped region are partially overlapped with the gate.

2. The HV MOS transistor device according to claim 1, wherein a width of the second doped region is larger than a width of the first doped region.

3. The HV MOS transistor device according to claim 1, wherein the second doped region contacts the drain region.

4. The HV MOS transistor device according to claim 3, wherein the second doped region overlaps with the drain region.

5. The HV MOS transistor device according to claim 1, further comprising a deep well region having the first conductivity type.

6. The HV MOS transistor device according to claim 5, wherein the source region, the drain region, the first doped region, and the second doped region are all formed in the deep well region.

7. The HV MOS transistor device according to claim 1, wherein the first doped region is a non-continuous doped region having a plurality of gaps formed therein.

8. A HV MOS transistor device comprising:
a substrate;
a gate positioned on the substrate;
a drain region formed in the substrate, the drain region having a first conductivity type;
a source region formed in the substrate, the source region having the first conductivity type;
a first doped region formed in between the source region and the drain region, the first doped region having a second conductivity type complementary to the first conductivity type; and
a second doped region formed under a bottom of the first doped region, the second doped region having the first conductivity type,
wherein the first doped region and the second doped region are partially overlapped with the gate.

9. The HV MOS transistor device according to claim 8, wherein a width of the second doped region is larger than a width of the first doped region.

10. The HV MOS transistor device according to claim 8, further comprising a deep well region having the first conductivity type.

11. The HV MOS transistor device according to claim 10, wherein the source region, the drain region, the first doped region, and the second doped region are all formed in the deep well region.

12. The HV MOS transistor device according to claim 8, wherein the first doped region is a non-continuous doped region having a plurality of gaps formed therein.

13. A HV MOS transistor device comprising:
a substrate;
a gate positioned on the substrate;
a drain region formed in the substrate, the drain region having a first conductivity type;
a source region formed in the substrate, the source region having the first conductivity type;
a first doped region formed in between the source region and the drain region, the first doped region having a second conductivity type complementary to the first conductivity type; and
a pair of second doped regions respectively formed over a top of the first doped region and under a bottom of the first doped region, the second doped regions having the first conductivity type,
wherein the first doped region and the second doped regions are partially overlapped with the gate.

14. The HV MOS transistor device according to claim 13, wherein a width of the second doped regions is larger than a width of the first doped region.

15. The HV MOS transistor device according to claim 13, wherein the second doped region formed over the top of the first doped region contacts the drain region.

16. The HV MOS transistor device according to claim 15, wherein the second doped region overlaps with the drain region.

17. The HV MOS transistor device according to claim 13, further comprising a deep well region having the first conductivity type.

18. The HV MOS transistor device according to claim 17, wherein the source region, the drain region, the first doped region, and the second doped regions are all formed in the deep well region.

19. The HV MOS transistor device according to claim 13, wherein the first doped region is a non-continuous doped region having a plurality of gaps formed therein.
